(19) United States
(12) Patent Application Publication
(10) Pub. No.: US 2025/0305887 A1
(43) Pub. Date: Oct. 2, 2025

(54) INTEGRATED CIRCUIT OF USING SAME CURRENT SOURCE TO BIAS DIODES WITH DIFFERENT SIZES FOR GENERATING AT LEAST ONE OF DIGITAL BANDGAP VALUE AND TEMPERATURE VALUE AND ASSOCIATED SIGNAL PROCESSING METHOD

(71) Applicant: Airoha Technology Corp., Hsinchu City (TW)

(72) Inventor: Wei-Chen Shen, Hsinchu City (TW)

(73) Assignee: Airoha Technology Corp., Hsinchu City (TW)

(21) Appl. No.: 18/619,205

(22) Filed: Mar. 28, 2024

(51) Int. Cl. G01K 7/01; H03K 17/51

(52) U.S. Cl. CPC G01K 7/01; H03K 17/51; G01K 2219/00

(57) ABSTRACT

An integrated circuit includes a current source, a diode device, a switch circuit, an analog-to-digital converter (ADC), and a processing circuit. The current source provides a reference current. The switch circuit enables the diode device to provide a first diode with a first size for receiving the reference current during a first interval, and enables the diode device to provide a second diode with a second size for receiving the reference current during a second interval. The ADC converts a first voltage across the first diode into a first diode voltage value, and converts a second voltage across the second diode into a second diode voltage value. The processing circuit performs an arithmetic operation upon the first diode voltage value and the second diode voltage value to generate a digital bandgap value.

### BACKGROUND OF THE INVENTION

### 1. Field of the Invention

The present invention relates to an integrated circuit design, and more particularly, to an integrated circuit of using the same current source to bias diodes with different sizes for generating at least one of a digital bandgap value and a temperature value and an associated signal processing method.

### 2. Description of the Prior Art

A temperature sensor is a device that detects and measures hotness and coolness and converts it into an electrical signal. For example, diodes can be used as temperature sensors in a variety of integrated circuits (chips). In a conventional temperature sensor design, a voltage across a diode is measured and then converted from an analog domain to a digital domain for further processing. The diode may have sensor (diode) mismatch, and therefore needs proper calibration. In addition, an analog-to-digital converter (ADC) may have reference voltage mismatch, and therefore needs a very accurate voltage source such as an analog bandgap reference circuit. Thus, there is a need for an innovative temperature sensor design which can generate a digital temperature value under a condition that the sensor (diode) mismatch is low and no accurate ADC reference voltage is needed.

### SUMMARY OF THE INVENTION

One of the objectives of the present invention is to provide an integrated circuit of using the same current source to bias diodes with different sizes for generating at least one of a digital bandgap value and a temperature value and an associated signal processing method.

According to a first aspect of the present invention, an exemplary integrated circuit is disclosed. The exemplary integrated circuit includes a current source, a diode device, a switch circuit, an analog-to-digital converter (ADC), and a processing circuit. The current source is arranged to provide a reference current. The switch circuit is coupled between the current source and the diode device. The switch circuit is arranged to enable the diode device to provide a first diode with a first size for receiving the reference current during a first interval, and is further arranged to enable the diode device to provide a second diode with a second size for receiving the reference current during a second interval, wherein the first size is different from the second size, and each of the first diode and the second diode is biased by the same current source. The ADC is arranged to convert a first voltage across the first diode into a first diode voltage value, and convert a second voltage across the second diode into a second diode voltage value. The processing circuit is arranged to perform an arithmetic operation upon the first diode voltage value and the second diode voltage value to generate a digital bandgap value.

According to a second aspect of the present invention, an exemplary signal processing method is disclosed. The exemplary signal processing method includes: during a first interval, enabling a diode device to provide a first diode with a first size for receiving a reference e current from a current source, and performing analog-to-digital conversion upon a first voltage across the first diode to generate a first diode voltage value; during a second interval, enabling the diode device to provide a second diode with a second size for receiving the reference current from the current source, and performing analog-to-digital conversion upon a second voltage across the second diode to generate a second diode voltage value, wherein the first size is different from the second size, and each of the first diode and the second diode is biased by the same current source; and performing an arithmetic operation upon the first diode voltage value and the second diode voltage value to generate a digital bandgap value.

According to a third aspect of the present invention, an exemplary integrated circuit is disclosed. The exemplary integrated circuit includes a current source, a diode device, a switch circuit, an ADC, and a processing circuit. The current source is arranged to provide a reference current. The switch circuit is coupled between the current source and the diode device. The switch circuit is arranged to enable the diode device to provide a first diode with a first size for receiving the reference current during a first interval, and is further arranged to enable the diode device to provide a second diode with a second size for receiving the reference current during a second interval, wherein the first size is different from the second size, and each of the first diode and the second diode is biased by the same current source. The ADC is arranged to convert a first voltage across the first diode into a first diode voltage value, and convert a second voltage across the second diode into a second diode voltage value. The processing circuit is arranged to perform an arithmetic operation upon the first diode voltage value and the second diode voltage value to generate a temperature value.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an integrated circuit according to an embodiment of the present invention.

FIG. 2 is a diagram illustrating another integrated circuit according to an embodiment of the present invention.

FIG. 3 is a flowchart illustrating a signal processing method according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

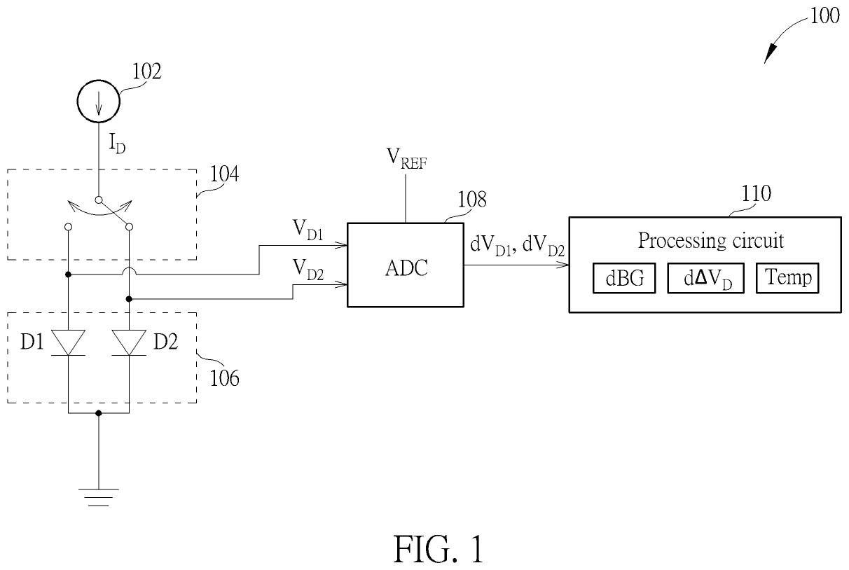

FIG. 1 is a diagram illustrating an integrated circuit according to an embodiment of the present invention. For example, the integrated circuit 100 may be a temperature sensor chip. For another example, the integrated circuit 100 may be any signal processing chip that adopts the proposed digital bandgap design. As shown in FIG. 1, the integrated circuit 100 includes a current source 102, a switch circuit 104, a diode device 106, an analog-to-digital converter (ADC) 108, and a processing circuit 110. The current source 102 is a circuit designed to provide a reference current I_{D}. The switch circuit 104 is coupled between the current source 102 and the diode device 106. In this embodiment, the diode device 106 includes two diode components D1 and D2 with different sizes (i.e., different cross-sectional areas). For example, each of the diode components D1 and D2 may be implemented using a diode-connected transistor such as a bipolar junction transistor (BJT) or a metal-oxide-semiconductor field-effect transistor (MOSFET), and a size ratio (area ratio) of diode components D1 and D2 may be 1:M.

The switch circuit 104 is arranged to enable the diode device 106 to provide a first diode with a first size (e.g., diode component D1) for receiving the reference current I_{D} during a first interval, and is further arranged to enable the diode device 106 to provide a second diode with a second size (e.g., diode component D2) for receiving the reference current I_{D} during a second interval, where the first interval and the second interval are non-overlapping intervals. During the first interval, the switch circuit 104 connects the diode component D1 to the current source 102, and disconnects the diode component D2 from the current source 102. Hence, the diode component D1 acts as a diode with a small size (small area). During the second interval, the switch circuit 104 disconnects the diode component D1 from the current source 102, and connects the diode component D2 to the current source 102. Hence, the diode component D2 acts as a diode with a large size (large area).

It should be noted that each of the first diode (e.g., diode component D1) and the second diode (e.g., diode component D2) is biased by the same current source 102. In other words, each of the first diode (e.g., diode component D1) and the second diode (e.g., diode component D2) is forced to have the same diode current I_{D} when operating in the forward bias region. Due to the fact that the first diode (e.g., diode component D1) and the second diode (e.g., diode component D2) have different sizes, a first voltage V_{D1} across the first diode (e.g., diode component D1) is different from a second voltage V_{D2} across the second diode (e.g., diode component D2).

The ADC 108 operates under a reference voltage V_{REF}. In this embodiment, the reference voltage V_{REF} is not required to be provided from a very accurate voltage source such as an analog bandgap reference circuit. For example, a less accurate supply voltage V_{DD} may be used as the reference voltage V_{REF} of the ADC 108. The ADC 108 is arranged to perform analog-to-digital conversion upon the first voltage V_{D1} across the first diode (e.g., diode component D1) to generate a first diode voltage value dV_{D1} (which is a digital output indicative of the analog voltage V_{D1}), and perform analog-to-digital conversion upon the second voltage V_{D2} across the second diode (e.g., diode component D2) to generate a second diode voltage value dV_{D2} (which is a digital output indicative of the analog voltage V_{D2}), where the prefix “d” means a digital format.

The processing circuit 110 is arranged to perform an arithmetic operation upon the first diode voltage value dV_{D1} and the second diode voltage value dV_{D2} to generate a digital bandgap value dBG. Specifically, the arithmetic operation may include calculating a diode voltage difference value dΔV_{D} between the first diode voltage value dV_{D1} and the second diode voltage value dV_{D2} (i.e., dΔV_{D}=dV_{D1}−dV_{D2}), where the prefix “d” means a digital format; and calculating the digital bandgap value dBG according to the diode voltage difference value dΔV_{D} and a diode voltage value dV_{D}, wherein the diode voltage value dV_{D} is selected from the first diode voltage value dV_{D1} and the second diode voltage value dV_{D2} (i.e., dV_{D}=dV_{D1} or dV_{D}=dV_{D2}). The computation of the digital bandgap value dBG may be expressed using the following formula.

$$dBG = {dV}_{D} + B * d Δ {V}_{D} , where B is a constant \qquad ( 1 )$$

It should be noted that the diode voltage difference value dΔV_{D} is a proportional to absolute temperature (PTAT) term. An analog diode voltage difference ΔV_{D} between two analog diode voltages V_{D1} and V_{D2} may be expressed using the following formula.

$$Δ {V}_{D} = {V}_{D 1} - {V}_{D 2} = \frac{kT}{q} ln ( \frac{\frac{{I}_{D 1}}{{I}_{S 1}} + 1}{\frac{{I}_{D 2}}{{I}_{S 2}} + 1} ) \qquad ( 2 )$$

In above formula (2), k is the Boltzmann constant, T is the absolute temperature of the PN junction, q is the elementary charge, I_{D1} is the diode current of the first diode, I_{D2} is the diode current of the second diode, I_{S1} is the reverse saturation current of the first diode, and I_{S2} is the reverse saturation current of the second diode.

If the first diode and the second diode are both biased by the same current source (e.g., current source 102 shown in FIG. 1), the diode current I_{D1} of the first diode and the diode current I_{D2} of the second diode are both equal to the same reference current I_{D} supplied by the current source (i.e., I_{D1}=I_{D2}=I_{D}). Moreover, the reverse saturation current (e. g., I_{S(1 or 2)}˜=1 pA) is much smaller than the

$$\frac{\frac{{I}_{D 1}}{{I}_{S 1}} + 1}{\frac{{I}_{D 2}}{{I}_{S 2}} + 1}$$

Assuming in diode current (e. g., I_{D(1 or 2)}˜=1˜10 uA). Hence, the term

$$( i . e . , C = \frac{{I}_{S 2}}{{I}_{S 1}} ) .$$

The formula (2) can be regarded as a constant C Assuming that a size ratio of the two diodes is 1:M, the reverse saturation current I_{S2} is M times as large as the reverse saturation current I_{S1}

$$( i . e . , \frac{{I}_{S 2}}{{I}_{S 1}} = M ) .$$

$$Δ {V}_{D} = {V}_{D 1} - {V}_{D 2} = \frac{kT}{q} ln M \qquad ( 3 )$$

Hence, the analog diode voltage difference dΔV_{D} is proportional to absolute temperature and almost independent of process variation (PV) if I_{D1}=I_{D2}.

In contrast to the diode voltage difference value dΔV_{D} being a PTAT term, the diode voltage value dV_{D1} in formula (1) is a complementary to absolute temperature (CTAT) term due to the fact that a reverse saturation current of a diode strongly depends on temperature. Hence, with a proper setting of the constant B in formula (1), the digital bandgap value dBG can be temperature independent.

In some embodiments of the present invention, the constant B may be determined during a wafer chip probing (CP) process. For example, one wafer may include a plurality of semiconductor dies, each having the integrated circuit 100 shown in FIG. 1. Regarding each semiconductor die tested during the wafer CP process, each of the first diode voltage value dV_{D1} and the second diode voltage value dV_{D2} is measured twice, including one measurement at low temperature and another measurement at high temperature. Regarding each of candidate values of the constant B, two digital bandgap values dBG are calculated for each semiconductor die, including one digital bandgap value dBG calculated for low temperature according to diode voltage values dV_{D2} and dV_{D2} measured at low temperature, and another digital bandgap value dBG calculated for high temperature according to diode voltage values dV_{D1} and dV_{D2} measured at high temperature. These digital bandgap values dBG provided from all tested semiconductor dies are collected for standard deviation (STDEV) analysis. For example, one STDEV value of all digital bandgap values dBG obtained under one candidate value of the constant B is calculated. A candidate value of the constant B that can lead to a minimum STDEV value among STDEV values calculated for all candidate values of the constant B is selected as a target value of the constant B. However, this is for illustrative purposes only, and is not meant to be a limitation of the present invention. In practice, any means capable of setting the constant B that can make the digital bandgap value dBG have a zero temperature coefficient may be employed.

After the digital bandgap value dBG is obtained by the processing circuit 110, the digital bandgap value dBG can be used as a reference voltage value needed by a variety of applications. For example, the digital bandgap value dBG can be used by a digital output temperature sensor. Hence, the processing circuit 110 is further arranged to perform another arithmetic operation upon the diode voltage difference value dΔV_{D} and the digital bandgap value dBG to generate a temperature value Temp (which is a digital output indicative of temperature integrated circuit 100). Specifically, the computation of the temperature value Temp may be expressed using the following formula.

$$Temp = \frac{d Δ {V}_{D}}{dBG} \qquad ( 4 )$$

The temperature value Temp is set by using the digital bandgap value dBG as a denominator to divide the diode voltage difference value dΔV_{D}. Compared to a typical temperature sensor design which uses a diode voltage of a single diode that needs calibration, the proposed temperature sensor design uses the PV-independent diode voltage difference value dΔV_{D}. In this way, the proposed temperature sensor design has much lower sensor (diode) mismatch. Furthermore, compared to a typical temperature sensor design which requires an ADC reference voltage provided from a very accurate voltage source such as a large-sized analog bandgap reference circuit, the proposed temperature sensor design uses a digital bandgap value dBG obtained by simple computation in a digital domain. In this way, the ADC 108 does not need an accurate reference voltage V_{REF}, and the large-sized analog bandgap reference circuit can be omitted for cost and area saving.

Regarding the embodiment shown in FIG. 1, only one of the diode components D1 and D2 is selected at a time. That is, the diode components D1 and D2 may be regarded as two separate diodes that are responsible for acting as two diodes with different sizes needed by the proposed digital bandgap design (or the proposed temperature sensor design). However, this is for illustrative purposes only, and is not meant to be a limitation of the present invention. In an alternative design, two diode components may be jointly used to act as a diode with a large size needed by the proposed digital bandgap design (or the proposed temperature sensor design).

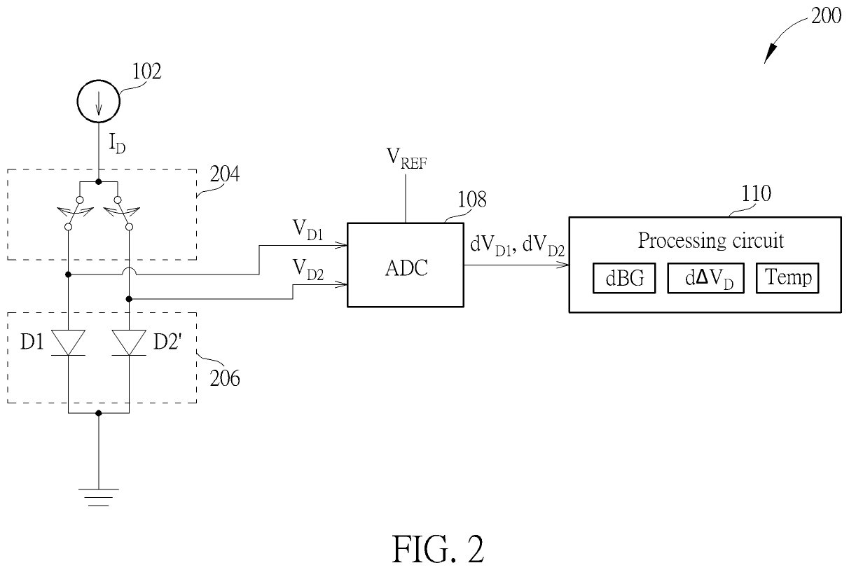

FIG. 2 is a diagram illustrating another integrated circuit according to an embodiment of the present invention. For example, the integrated circuit 200 may be a temperature sensor chip. For another example, the integrated circuit 200 may be any signal processing chip that adopts the proposed digital bandgap design. The major difference between the integrated circuits 100 and 200 is that the switch circuit 204 allows multiple diode components to be selected at a time. The switch circuit 204 is coupled between the current source 102 and the diode device 206. In this embodiment, the diode device 206 includes two diode components D1 and D2′. For example, each of the diode components D1 and D2′ may be implemented using a diode-connected transistor such as a BJT or a MOSFET, and a size ratio (area ratio) of diode components D1 and D2′ may be 1: (M-1).

The switch circuit 204 is arranged to enable the diode device 106 to provide a first diode with a first size (e.g., diode component D1) for receiving the reference current I_{D} during a first interval, and is further arranged to enable the diode device 206 to provide a second diode with a second size (e.g., diode components D1 and D2′) for receiving the reference current I_{D} during a second interval, where the first interval and the second interval are non-overlapping intervals. During the first interval, the switch circuit 204 connects the diode component D1 to the current source 102, and disconnects the diode component D2′ from the current source 102. Hence, the diode component D1 acts as a diode with a small size (small area). During the second interval, the switch circuit 204 connects the diode component D1 to the current source 102, and also connects the diode component D2′ to the current source 102. Hence, the diode components D1 and D2′ jointly acts as a diode with a large size (large area). The same objective of creating a first voltage V_{D1} across the first diode (e.g., diode component D1 selected during the first interval) and a second voltage V_{D2} (V_{D2}≠V_{D1}) across the second diode (e.g., diode components D1 and D2′ both selected during the second interval) under the same bias current I_{D} is achieved.

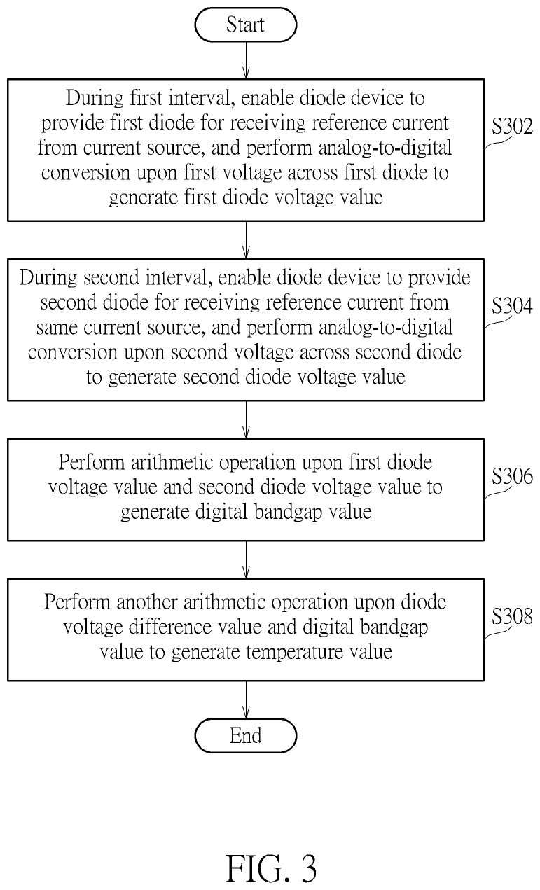

FIG. 3 is a flowchart illustrating a signal processing method according to an embodiment of the present invention. The signal processing method may be employed by any of the integrated circuits 100 and 200. Provided that the result is substantially the same, the steps are not required to be executed in the exact order shown in FIG. 3. At step S302, the switch circuit 104/204 enables the diode device 106/206 to provide a first diode with a first size for receiving the reference current I_{D} from the current source 102 during a first interval, and the ADC 108 performs analog-to-digital conversion upon the first voltage Voi across the first diode to generate the first diode voltage value dV_{D1} during the first interval. At step S304, the switch circuit 104/204 enables the diode device 106/206 to provide a second diode with a second size for receiving the reference current Ip from the same current source 102 during a second interval, and the ADC 108 performs analog-to-digital conversion upon the second voltage V_{D2} across the second diode to generate the second diode voltage value dV_{D2} during the second interval. At step S306, the processing circuit 110 performs an arithmetic operation upon the first diode voltage value dVDI and the second diode voltage value dV_{D2} to generate the digital bandgap value dBG. At step S308, the processing circuit 110 performs another arithmetic operation upon the diode voltage difference value dAVD and the digital bandgap value dBG to generate the temperature value Temp. As a person skilled in the art can readily understand details of steps shown in FIG. 3 after reading above paragraphs directed to the embodiments shown in FIG. 1 and FIG. 2, further description is omitted here for brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated circuit comprising:
a current source, arranged to provide a reference current;
a diode device;
a switch circuit, coupled between the current source and the diode device, wherein the switch circuit is arranged to enable the diode device to provide a first diode with a first size for receiving the reference current during a first interval, and is further arranged to enable the diode device to provide a second diode with a second size for receiving the reference current during a second interval, wherein the first size is different from the second size, and each of the first diode and the second diode is biased by the same current source;
an analog-to-digital converter (ADC), arranged to convert a first voltage across the first diode into a first diode voltage value, and convert a second voltage across the second diode into a second diode voltage value; and
a processing circuit, arranged to perform an arithmetic operation upon the first diode voltage value and the second diode voltage value to generate a digital bandgap value.

2. The integrated circuit of claim 1, wherein the arithmetic operation performed by the processing circuit comprises:
calculating a diode voltage difference value between the first diode voltage value and the second diode voltage value; and
calculating the digital bandgap value according to the diode voltage difference value and a diode voltage value, wherein the diode voltage value is selected from the first diode voltage value and the second diode voltage value.

3. The integrated circuit of claim 2, wherein the digital bandgap value is set by a sum of the diode voltage value and a product of a constant and the diode voltage difference value.

4. The integrated circuit of claim 2, wherein the processing circuit is further arranged to perform another arithmetic operation upon the diode voltage difference value and the digital bandgap value to generate a temperature value.

5. The integrated circuit of claim 4, wherein the temperature value is set by using the digital bandgap value as a denominator to divide the diode voltage difference value.

6. The integrated circuit of claim 1, wherein the diode device comprises:
a first diode component; and
a second diode component;
wherein during the first interval, the switch circuit connects the first diode component to the current source, and disconnects the second diode component from the current source; and during the second interval, the switch circuit disconnects the first diode component from the current source, and connects the second diode component to the current source.

7. The integrated circuit of claim 1, wherein the diode device comprises:
a first diode component; and
a second diode component;
wherein during the first interval, the switch circuit connects the first diode component to the current source, and disconnects the second diode component from the current source; and during the second interval, the switch circuit connects the first diode component to the current source, and connects the second diode component to the current source.

8. A signal processing method comprising:
during a first interval, enabling a diode device to provide a first diode with a first size for receiving a reference current from a current source, and performing analog-to-digital conversion upon a first voltage across the first diode to generate a first diode voltage value;
during a second interval, enabling the diode device to provide a second diode with a second size for receiving the reference current from the current source, and performing analog-to-digital conversion upon a second voltage across the second diode to generate a second diode voltage value, wherein the first size is different from the second size, and each of the first diode and the second diode is biased by the same current source; and
performing an arithmetic operation upon the first diode voltage value and the second diode voltage value to generate a digital bandgap value.

9. The signal processing method of claim 8, wherein the arithmetic operation comprises:
calculating a diode voltage difference value between the first diode voltage value and the second diode voltage value; and
calculating the digital bandgap value according to the diode voltage difference value and a diode voltage value, wherein the diode voltage value is selected from the first diode voltage value and the second diode voltage value.

10. The signal processing method of claim 9, wherein the digital bandgap value is set by a sum of the diode voltage value and a product of a constant and the diode voltage difference value.

11. The signal processing method of claim 10, further comprising:
determining the constant during a wafer chip probing (CP) process.

12. The signal processing method of claim 9, further comprising:
performing another arithmetic operation upon the diode voltage difference value and the digital bandgap value to generate a temperature value.

13. The signal processing method of claim 12, wherein the temperature value is set by using the digital bandgap value as a denominator to divide the diode voltage difference value.

14. The signal processing method of claim 8, wherein enabling the diode device to provide the first diode with the first size for receiving the reference current from the current source comprises:
connecting a first diode component of the diode device to the current source; and
disconnecting a second diode component of the diode device from the current source; and
enabling the diode device to provide the second diode with the second size for receiving the reference current from the current source comprises:
disconnecting the first diode component from the current source;
and connecting the second diode component to the current source.

15. The signal processing method of claim 8, wherein enabling the diode device to provide the first diode with the first size for receiving the reference current from the current source comprises:
connecting a first diode component of the diode device to the current source; and
disconnecting a second diode component of the diode device from the current source; and
enabling the diode device to provide the second diode with the second size for receiving the reference current from the current source comprises:
connecting the first diode component to the current source; and
connecting the second diode component to the current source.

16. An integrated circuit comprising:
a current source, arranged to provide a reference current;
a diode device;
a switch circuit, coupled between the current source and the diode device, wherein the switch circuit is arranged to enable the diode device to provide a first diode with a first size for receiving the reference current during a first interval, and is further arranged to enable the diode device to provide a second diode with a second size for receiving the reference current during a second interval, wherein the first size is different from the second size, and each of the first diode and the second diode is biased by the same current source;
an analog-to-digital converter (ADC), arranged to convert a first voltage across the first diode into a first diode voltage value, and convert a second voltage across the second diode into a second diode voltage value; and
a processing circuit, arranged to perform an arithmetic operation upon the first diode voltage value and the second diode voltage value to generate a temperature value.

17. The integrated circuit of claim 16, wherein the arithmetic operation performed by the processing circuit comprises:
calculating a diode voltage difference value between the first diode voltage value and the second diode voltage value, where calculation of the temperature value is based at least partly on the diode voltage difference value.

18. The integrated circuit of claim 16, wherein the diode device comprises:
a first diode component; and
a second diode component;
wherein during the first interval, the switch circuit connects the first diode component to the current source, and disconnects the second diode component from the current source; and during the second interval, the switch circuit disconnects the first diode component from the current source, and connects the second diode component to the current source.

19. The integrated circuit of claim 16, wherein the diode device comprises:
a first diode component; and
a second diode component;
wherein during the first interval, the switch circuit connects the first diode component to the current source, and disconnects the second diode component from the current source; and during the second interval, the switch circuit connects the first diode component to the current source, and connects the second diode component to the current source.
